(19) United States
(12) Patent Application Publication
(10) Pub. No.: US 2026/0236425 A1
(43) Pub. Date: Aug. 13, 2026

(54) STORAGE CONTROLLER DEVICE CONFIGURED TO PERFORM A COMPUTATION, MULTI-CHIP PACKAGE AND COMPUTING SYSTEM USING THE STORAGE CONTROLLER DEVICE

(71) Applicant: SK hynix Inc., Icheon-si Gyeonggi-do (KR)

(72) Inventors: Yangsoo PARK, San Jose, CA (US); Seong Ju LEE, San Jose, CA (US); Sunjoo KIM, San Jose, CA (US)

(73) Assignee: SK hynix Inc., Icheon-si Gyeonggi-do (KR)

(21) Appl. No.: 19/535,430

(22) Filed: Feb. 10, 2026

Related U.S. Application Data
(60) Provisional application No. 63/756,914, filed on Feb. 11, 2025.

(30) Foreign Application Priority Data
Jan. 5, 2026 (KR) 10-2026-0001159

(51) Int. Cl. G06F 13/42; G06F 13/16

(52) U.S. Cl. CPC G06F 13/4282; G06F 13/1673

(57) ABSTRACT

A storage controller device is coupled to a host, a storage memory, and a computational memory, and is configured to directly move data between the storage memory and the computational memory. The storage controller device is configured to perform a computational operation on computational data transmitted from the host and computational data transmitted from the computational memory.

### CROSS-REFERENCES TO RELATED APPLICATION

The present application claims benefit under 35 U.S.C. § 119(e) of U.S. Provisional application No. 63/756,914 filed on Feb. 11, 2025, and which claims priority under 35 U.S.C. § 119(a) to Korean application number 10-2026-0001159 filed on Jan. 5, 2026, in the Ministry of Intellectual Property, the entire contents of which applications are incorporated herein by reference.

### BACKGROUND

### 1. Technical Field

Various embodiments generally relate to integrated circuit technology, and, more particularly, to a storage controller device configured to perform a computation, a multi-chip package using the storage controller device, and a computing system using the storage controller device.

### 2. Related Art

A conventional computing system may include a host, a main memory, a storage system on chip, and a storage memory. In general, because a memory manufacturer manufactures the main memory, the storage system on chip, and the storage memory together, the storage system on chip, the storage memory, and the main memory may be packaged as a single package and provided as one multi-chip package. Because the main memory does not have a separate connection with the storage system on chip, the main memory may be provided in the multi-chip package or may be provided outside the multi-chip package. Large-capacity data such as big data may be stored in the storage memory. In order to perform a computation operation using the big data, the host may move data stored in the storage memory to the main memory and perform the computation operation while performing data input/output operations with the main memory. However, data stored in the storage memory is provided to the host through the storage system on chip, and a serial link connecting the storage system on chip and the host have a small bandwidth. Accordingly, a large amount of time may be required for data to be moved from the storage memory to the main memory, and performance of the computing system may be degraded.

### SUMMARY

In an embodiment, a storage controller device includes a serial interface, a storage controller, a memory controller, a computational engine, and a memory interface. The serial interface may couple a host and an internal bus. The storage controller may be coupled to the internal bus and may be coupled to a storage memory through a storage bus. The memory controller may be coupled to the internal bus. The computational engine may be coupled to the internal bus. The memory interface may be coupled to a computational memory through a memory bus and may be configured to selectively couple the computational engine and the memory controller to a data bus of the memory bus based on a command address signal of the memory bus.

In an embodiment, a computing system includes a host and a storage controller device. The host may be coupled to a main memory through a first memory bus. The storage controller device may be coupled to the host through a serial bus, may be coupled to a storage memory through a storage bus, and may be coupled to a computational memory through a second memory bus. The storage controller device may be configured to perform a computation on first computational data transmitted from the host through the serial bus and second computational data provided from the computational memory through the second memory bus.

In an embodiment, a method of operating a computing system includes providing first computational data to a storage memory by a host through a storage controller device. The method may include directly moving the first computational data stored in the storage memory to a computational memory by the storage controller device. The method may include providing second computational data to the storage controller device by the host, and providing the first computational data to the storage controller device by the computational memory. The method may further include performing a computational operation on the first computational data and the second computational data by the storage controller device.

### BRIEF DESCRIPTION OF THE DRAWINGS

FIG. 1 is a diagram illustrating a configuration of a computing system according to an embodiment of the present disclosure.

FIG. 2 is a diagram illustrating a configuration and a connection relationship of a memory controller, a memory interface, a computational memory, and a computational engine illustrated in FIG. 1.

FIGS. 3A, 3B, and FIG. 3C are diagrams illustrating operations of the computing system according to an embodiment of the present disclosure.

### DETAILED DESCRIPTION

Terms such as “first,” “second,” etc., are used to distinguish between various elements and do not imply size, order, priority, quantity, or importance of the elements. For example, a first element may be named as a second element in one example, and the second element may be named as a first element in another example. It will be understood that when an element or layer etc., is referred to as being “on,” “connected to” or “coupled to” another element etc., it can be directly on, connected or coupled to the other element etc., or intervening elements etc., may be present. In contrast, when an element etc., is referred to as being “directly on,” “directly connected to” or “directly coupled to” another element etc., there are no intervening elements etc., present.

Various embodiments of the present disclosure relate to a storage controller device that integrates data movement, memory control, and computational capability, as well as to a multi-chip package and a computing system including the same. In conventional computing systems, computational operations on large-capacity data stored in a storage memory typically require transferring the data to a host and a main memory through a serial interface, which may become a performance bottleneck due to limited bandwidth. Various embodiments of the present disclosure address this limitation by enabling computational operations to be performed within or near the storage controller device, thereby reducing data movement over bandwidth-constrained interfaces.

In accordance with various embodiments of the present disclosure, the storage controller device may include a serial interface for communication with a host, a storage controller coupled to a storage memory, a memory controller coupled to a computational memory, a computational engine configured to perform computation, and a memory interface configured to selectively couple the memory controller or the computational engine to a data bus of the memory bus. Through this architecture, data may be directly moved between the storage memory and the computational memory under control of the storage controller device, and computational operations may be performed using computational data provided from the host and computational data stored in the computational memory, without routing such data through the host or a main memory.

Further, various embodiments of the present disclosure provide a computing system and methods of operating the computing system in which the storage controller device performs computational operations in coordination with data transfers among the host, the storage memory, and the computational memory. In an embodiment, by allowing large-capacity computational data to be supplied from the computational memory and smaller-capacity computational data to be supplied from the host, and by performing computation within the storage controller device, overall system performance may be improved. In addition, in an embodiment, because the disclosed architecture may be implemented within a single package or a multi-chip package, compatibility with existing host systems may be maintained while enabling enhanced computation efficiency for applications such as artificial intelligence and high-performance computing.

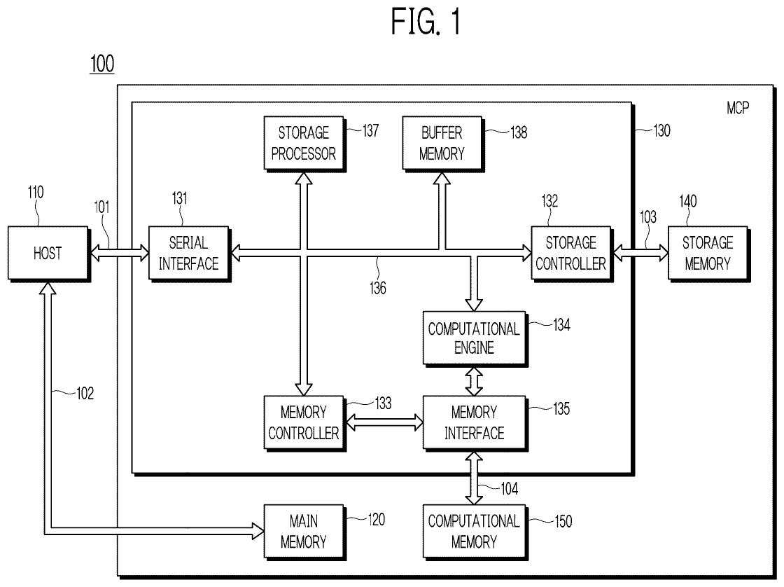

FIG. 1 is a diagram illustrating a configuration of a computing system 100 according to an embodiment of the present disclosure. Referring to FIG. 1, the computing system may include a host 110, a main memory 120, a storage controller device 130, a storage memory 140, and a computational memory 150. The host 110 may perform one or more operations according to a user input and may control signal processing in the computing system 100. The host 110 may perform data communication with the main memory 120 and may perform data communication with the storage memory 140 through the storage controller device 130. The host 110 may be coupled to the storage controller device 130 through a serial bus 101 and may communicate with the storage controller device 130 through the serial bus 101. The host 110 may transmit a system command address signal and data to the storage controller device 130 through the serial bus 101 and may receive data transmitted from the storage controller device 130 through the serial bus 101. The serial bus 101 may include one of PCIe (Peripheral Component Interconnect Express), a UFS (Universal Flash Storage) bus, and UCIe (Universal Chiplet Interconnect Express). The host 110 may be coupled to the main memory 120 through a first memory bus 102 and may communicate with the main memory 120 through the first memory bus 102. The host 110 may transmit a memory command address signal and data to the main memory 120 through the first memory bus 102 and may receive data transmitted from the main memory 120 through the first memory bus 102. The host 110 may include at least one processor. The processor may include one or more of a Central Processing Unit (CPU), a Graphic Processing Unit (GPU), a Neural Processing Unit (NPU), and an Application Processor (AP).

The main memory 120 is coupled to the host 110 through the first memory bus 102 and may store data provided from the host 110. The main memory 120 stores data related to an operation and a program performed by the host 110, and the host 110 may quickly access data stored in the main memory 120. The main memory 120 may be a volatile memory. For example, the main memory 120 may be DRAM (Dynamic Random Access Memory) and may include one of DDR (Double Data Rate) RAM, LPDDR (Low Power Double Data Rate) RAM, and GDDR (Graphic Double Data Rate) RAM. In addition, the main memory 120 may include one of a 3-dimensional stack memory, HBM (High Bandwidth Memory), and HMC (Hybrid Memory Cube). The main memory 120 may communicate with the host 110 through the first memory bus 102. The main memory 120 may receive the memory command address signal from the host 110 and, based on the memory command address signal, may store data transmitted from the host 110 or may output data stored in the main memory 120 to the host 110.

The storage controller device 130 may be coupled to the host 110 through the serial bus 101. The storage controller device 130 may be coupled to the storage memory 140 through a storage bus 103. The storage controller device 130 may be coupled to the computational memory 150 through a second memory bus 104. The storage controller device 130 might not have a separate connection with the main memory 120. The storage controller device 130 may relay communication among the host 110, the storage memory 140, and the computational memory 150. The storage controller device 130 may control a data input/output operation between the host 110 and the storage memory 140. The storage controller device 130 may receive a first command address signal from the host 110 through the serial bus 101 and may control data movement between the host 110 and the storage memory 140 based on the first command address signal. The storage controller device 130 may generate a storage command address signal based on the first command address signal. The storage command address signal may include a storage write command address signal and a storage read command address signal. During a storage memory write operation, the storage controller device 130 may generate the storage write command address signal based on the first command address signal and may transmit the storage write command address signal and data transmitted from the host 110 to the storage memory 140 through the storage bus 103. The storage memory 140 may store the data transmitted through the storage bus 103 based on the storage write command address signal in the storage memory 140. During a storage memory read operation, the storage controller device 130 may generate the storage read command address signal based on the first command address signal and may transmit the storage read command address signal to the storage memory 140 through the storage bus 103. The storage memory 140 may output data stored in the storage memory 140 based on the storage read command address signal and may transmit the data to the storage controller device 130 through the storage bus 103. The storage controller device 130 may transmit the data received through the storage bus 103 to the host 110 through the serial bus 101. The storage memory 140 may include a non-volatile memory device that may function as storage class memory. For example, the storage memory 140 may include flash memory, PRAM (Phase Change RAM), MRAM (Magnetic RAM), RRAM (Resistive RAM), and FRAM (Ferroelectric RAM).

The storage controller device 130 may control a data input/output operation between the host 110 and the computational memory 150. The storage controller device 130 may receive a second command address signal from the host 110 through the serial bus 101 and may control data movement between the host 110 and the computational memory 150 based on the second command address signal. The storage controller device 130 may generate a memory command address signal based on the second command address signal. The memory command address signal may include a memory write command address signal and a memory read command address signal. During a memory write operation, the storage controller device 130 may generate the memory write command address signal based on the second command address signal and may transmit the memory write command address signal and data transmitted from the host 110 to the computational memory 150 through the second memory bus 104. As used herein, a memory bus may include one or more command address buses, data buses, or combinations thereof for communicating with a memory device. The computational memory 150 may store the data transmitted through the second memory bus 104 in the computational memory 150 based on the memory write command address signal. During a memory read operation, the storage controller device 130 may generate the memory read command address signal based on the second command address signal and may transmit the memory read command address signal to the computational memory 150 through the second memory bus 104. The computational memory 150 may output data stored in the computational memory 150 based on the memory read command address signal and may transmit the data to the storage controller device 130 through the second memory bus 104. The storage controller device 130 may transmit the data received through the second memory bus 104 to the host 110 through the serial bus 101. The computational memory 150 may include a volatile memory device. For example, the computational memory 150 may include one of DDR (Double Data Rate) RAM, LPDDR (Low Power Double Data Rate) RAM, and GDDR (Graphic Double Data Rate) RAM. In an embodiment, the second memory bus 104 may be a wide input and output bus that may provide a large bandwidth, and the computational memory 150 may include one of a 3-dimensional stack (3DS) memory including a plurality of dies coupled through wire bonding, HBM (High Bandwidth Memory) including a plurality of dies coupled through TSVs, and HMC (Hybrid Memory Cube).

The storage controller device 130 may control a data input/output operation between the storage memory 140 and the computational memory 150. The storage controller device 130 may receive the first command address signal and the second command address signal from the host 110 through the serial bus 101 and may control data movement between the storage memory 140 and the computational memory 150 based on the first and second command address signals. When data is moved from the storage memory 140 to the computational memory 150, the storage controller device 130 may generate the storage read command address signal based on the first command address signal and may generate a memory write command address signal based on the second command address signal. The storage controller device 130 may transmit the storage read command address signal to the storage memory 140 through the storage bus 103 and may transmit the memory write command address signal to the computational memory 150 through the second memory bus 104. The storage memory 140 may output data stored in the storage memory 140 based on the storage read command address signal and may transmit the data to the storage controller device 130 through the storage bus 103. The storage controller device 130 may transmit the data transmitted through the storage bus 103 to the computational memory 150 through the second memory bus 104. The computational memory 150 may store data transmitted through the second memory bus 104 in the computational memory 150 based on the memory write command address signal. Conversely, when data is moved from the computational memory 150 to the storage memory 140, the storage controller device 130 may generate the storage write command address signal based on the first command address signal and may generate a memory read command address signal based on the second command address signal. The storage controller device 130 may transmit the storage write command address signal to the storage memory 140 through the storage bus 103 and may transmit the memory read command address signal to the computational memory 150 through the second memory bus 104. The computational memory 150 may output data stored in the computational memory 150 based on the memory read command address signal and may transmit the data to the storage controller device 130 through the second memory bus 104. The storage controller device 130 may transmit the data transmitted through the second memory bus 104 to the storage memory 140 through the storage bus 103. The storage memory 140 may store data transmitted through the storage bus 103 in the storage memory 140 based on the storage write command address signal.

The storage controller device 130 may perform a computational operation. The storage controller device 130 may receive first computational data from the host 110, may receive second computational data from the computational memory 150, and may perform the computational operation on the first and second computational data. The computational operation may include a linear operation such as a GEMV (General Matrix Vector Multiplication) operation and a non-linear operation such as an activation function operation. For example, the first computational data may be vector data, and the second computational data may be weight data. The storage controller device 130 may receive a computation command address signal from the host 110 through the serial bus 101 and may perform the computational operation based on the computation command address signal. The storage controller device 130 may generate the memory read command address signal based on the computation command address signal and may transmit the memory read command address signal to the computational memory 150 through the second memory bus 104. The computational memory 150 may output data stored in the computational memory 150 as the second computational data based on the memory read command address signal. The storage controller device 130 may receive the second computational data through the second memory bus 104. The storage controller device 130 may receive the first computational data from the host 110 through the serial bus 101. The storage controller device 130 may perform the computational operation on the first and second computational data to generate computation result data. The storage controller device 130 may provide the computation result data to at least one of the host 110, the storage memory 140, and the computational memory 150. For example, the storage controller device 130 may store the computation result data in the computational memory 150 and then may move the computation result data from the computational memory 150 to at least one of the host 110 and the storage memory 140.

The storage controller device 130 may include a serial interface 131, a storage controller 132, a memory controller 133, a computational engine 134, and a memory interface 135. The serial interface 131 may be coupled to the host 110 through the serial bus 101 and may be coupled to an internal bus 136 of the storage controller device 130. The storage controller device 130 may communicate with the host 110 through the serial interface 131. The serial interface 131 may output, to the internal bus 136, the first command address signal, the second command address signal, the computation command address signal, and the data transmitted from the host 110 through the serial bus 101, and may transmit data transmitted through the internal bus 136 to the host 110 through the serial bus 101.

The storage controller 132 may be coupled to the internal bus 136 and may be coupled to the storage memory 140 through the storage bus 103. As used herein, a storage controller refers to a hardware circuit block configured to manage access to a storage memory, including generation of storage command address signals and control of data transfer. The storage controller 132 may communicate with the storage memory 140 through the storage bus 103. The storage controller 132 may receive the first command address signal through the internal bus 136, may generate the storage command address signal from the first command address signal, and may provide the storage command address signal to the storage memory 140 through the storage bus 103. The storage controller 132 may receive data transmitted from the serial interface 131 through the internal bus 136 and may provide the received data to the storage memory 140 through the storage bus 103. The storage controller 132 may receive data transmitted from the storage memory 140 through the storage bus 103 and may transmit the received data to the internal bus 136.

The memory controller 133 may be coupled to the computational memory 150 through the second memory bus 104. As used herein, a memory controller refers to a hardware circuit block configured to control access to a memory device through a memory bus, including generation of memory command address signals and management of data transfer. The memory controller 133 may communicate with the computational memory 150 through the second memory bus 104. The memory controller 133 may receive the second command address signal and the computation command address signal from the serial interface 131 through the internal bus 136, may generate the memory command address signal from the second command address signal and the computation command address signal, and may provide the memory command address signal to the computational memory 150 through the second memory bus 104. The memory controller 133 may receive data transmitted through the internal bus 136 and may provide the received data to the computational memory 150 through the second memory bus 104. The memory controller 133 may receive data transmitted from the computational memory 150 through the second memory bus 104 and may transmit the received data to the internal bus 136.

The computational engine 134 may be coupled to the internal bus 136 and the second memory bus 104. As used herein, a computational engine may perform one or more arithmetic, logical, or data processing operations on data received through one or more buses. The computational engine 134 may receive the first computational data through the internal bus 136 and may receive the second computational data through the second memory bus 104. The computational engine 134 may perform a computational operation on the first and second computational data to generate computation result data. The computational engine 134 may include a plurality of processing elements, artificial intelligence accelerators, and data computation engines designed to efficiently perform specific computational tasks. The computational engine 134 may store the computation result data and may output the computation result data to the second memory bus 104.

The memory interface 135 may be coupled to the memory controller 133 and the computational engine 134 and may be coupled to the computational memory 150 through the second memory bus 104. As used herein, a data bus refers to one or more signal lines configured to transfer data, and may form a portion of a memory bus. The memory interface 135 may receive the memory command address signal and data transmitted from the memory controller 133 and may transmit the data to the computational memory 150 through the second memory bus 104. The memory interface 135 may receive data transmitted from the computational memory 150 through the second memory bus 104 and may transmit the data to one of the memory controller 133 and the computational engine 134. The second memory bus 104 may include a command address bus and a data bus. The memory command address signal may be transmitted from the memory interface 135 to the computational memory 150 through the command address bus. Data may be transmitted between the memory interface 135 and the computational memory 150 through the data bus. The memory interface 135 may selectively couple the memory controller 133 and the computational engine 134 to the computational memory 150. When the host 110 performs a data input/output operation with the computational memory 150 and when data is moved between the storage memory 140 and the computational memory 150, the memory interface 135 may couple the memory controller 133 to the computational memory 150 through the data bus of the second memory bus 104. When the computational operation is performed, the memory interface 135 may couple the computational engine 134 to the computational memory 150 through the data bus of the second memory bus 104. The memory interface 135 may selectively couple the memory controller 133 and the computational engine 134 to the data bus of the second memory bus 104 based on the memory command address signal. As used herein, a command address signal may include a memory command address signal, a computation command address signal, or a signal derived therefrom. For example, the memory interface 135 may couple one of the memory controller 133 and the computational engine 134 to the data bus based on a logic level of at least one bit of the memory command address signal received from the memory controller 133. The at least one bit of the memory command address signal may include information for distinguishing whether the memory command address signal is generated from the second command address signal or from the computation command address signal. When the memory command address signal is generated based on the second command address signal, the memory interface 135 may couple the data bus of the second memory bus 104 to the memory controller 133 such that data may be transmitted between the memory controller 133 and the computational memory 150. When the memory command address signal is generated based on the computation command address signal, the memory interface 135 may couple the data bus of the second memory bus 104 to the computational engine 134 such that data may be transmitted between the computational engine 134 and the computational memory 150. In an embodiment, the host 110 may provide a selection command address signal to the storage controller device 130. The memory controller 133 may generate a path selection signal based on the selection command address signal. The memory controller 133 may provide the path selection signal to the memory interface 135. The memory interface 135 may couple one of the memory controller 133 and the computational engine 134 to the data bus based on the path selection signal. For example, when the path selection signal has a logic high level, the memory interface 135 may couple the data bus of the second memory bus 104 to the memory controller 133. When the path selection signal has a logic low level, the memory interface 135 may couple the data bus of the second memory bus 104 to the computational engine 134.

The storage controller device 130 may further include a storage processor 137 and a buffer memory 138. The storage processor 137 may control communication between the serial interface 131 and the storage controller 132 and may control communication between the serial interface 131 and the memory controller 133. The storage processor 137 may perform various functions. For example, the storage processor 137 may map a logical address transmitted from the host 110 to a physical address of the storage memory 140, may perform wear leveling of the storage memory 140, and may perform error correction on data transmitted through the storage bus 103. In addition, in an embodiment, the storage processor 137 may manage bad blocks of the storage memory 140 and may mitigate read disturbance. In addition, the storage processor 137 may enqueue a plurality of commands transmitted from the host 110 into a queue and may schedule the plurality of commands according to priorities to determine a processing order of the plurality of commands.

In embodiments of the present disclosure, the terms “computational engine,” “memory interface,” and “storage processor” refer to one or more hardware circuit blocks. For example, the computational engine may include one or more processing elements, arithmetic circuits, data paths, registers, and control logic configured to perform computational operations. The memory interface may include one or more routing circuits, multiplexers, buffers, drivers/receivers, and associated control logic configured to selectively couple data paths and command/address paths of a memory bus. The storage processor may include one or more processors or microcontrollers, state machines, address translation circuitry, error correction circuitry, and memory management logic for controlling storage operations. The foregoing examples are provided for illustration, and the disclosed functions may be implemented using various combinations of dedicated logic circuits, programmable logic, or firmware-controlled hardware.

In an embodiment, the buffer memory 138 may store data output from the storage memory 140 or data to be stored in the storage memory 140 and may be provided to compensate for speeds of a relatively slow storage memory write operation and a storage memory read operation. The buffer memory 138 may function as a data cache for reducing an operational speed difference between the storage memory 140 and other components communicating with the storage memory 140. The buffer memory 138 may store a mapping table to allow the storage processor 137 to map the logical address to the physical address and may provide the mapping table to the storage processor 137. In an embodiment, the buffer memory 138 may increase efficiency of the storage memory write operation to extend a lifetime of the storage memory 140. The buffer memory 138 may include one of various types of RAM capable of operating at a high speed, such as SRAM (Static Random Access Memory).

In an embodiment, the storage controller device 130 and the storage memory 140 may be packaged as a single package and may be provided as one storage device. The main memory 120 and the computational memory 150 may be packaged as separate packages, respectively. In an embodiment, the storage controller device 130, the storage memory 140, and the computational memory 150 may be packaged as a single package and may be provided as a multi-chip package (MCP) and/or a multi-die package. The main memory 120 may be packaged as a separate package. In an embodiment, the storage controller device 130, the storage memory 140, the computational memory 150, and the main memory 120 may be packaged as a single package. In an embodiment, the storage controller device 130, the storage memory 140, the computational memory 150, and the main memory 120 may each be manufactured as chiplets and may be coupled to each other through chiplet interconnects within the one multi-chip package or the one multi-die package.

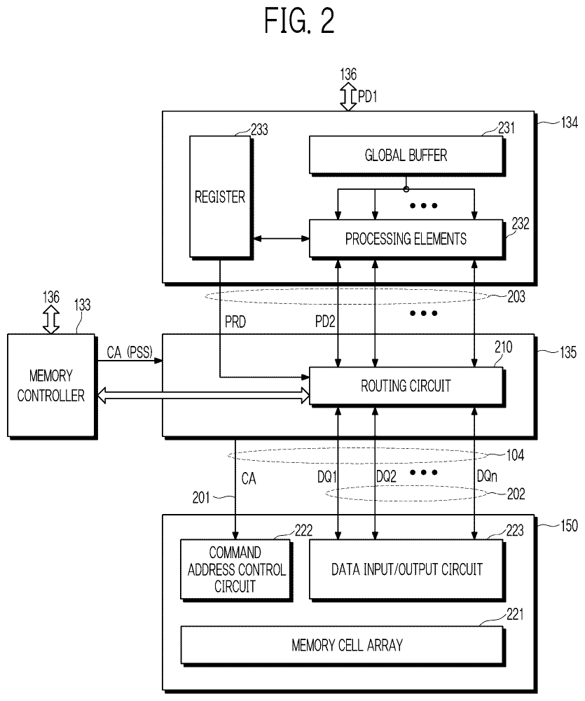

FIG. 2 is a diagram illustrating a configuration and a connection relationship of the memory controller 133, the memory interface 135, the computational memory 150, and the computational engine 134 illustrated in FIG. 1. Referring to FIG. 2, the memory interface 135 may include a routing circuit 210. The routing circuit 210 may be coupled to the memory controller 133 and the computational engine 134 and may be coupled to the computational memory 150 through the second memory bus 104. The routing circuit 210 may receive the memory command address signal CA from the memory controller 133 and may receive data from the memory controller 133 or may transmit data to the memory controller 133. The second memory bus 104 may include a command address bus 201 and a first data bus 202. The first data bus 202 may be a group of signal transmission lines for transmitting data among the second memory bus 104. The memory interface 135 may provide the memory command address signal CA provided from the memory controller 133 to the computational memory 150 through the command address bus 201. The routing circuit 210 may be coupled to the computational engine 134 through a second data bus 203. The routing circuit 210 may selectively couple the first data bus 202 to one of the memory controller 133 and the computational engine 134 based on the memory command address signal CA or the path selection signal PSS. The routing circuit 210 may couple the memory controller 133 to the first data bus 202 or may couple the computational engine 134 and/or the second data bus 203 to the first data bus 202 based on at least one bit of the memory command address signal CA. Alternatively, the routing circuit 210 may couple the memory controller 133 to the first data bus 202 or may couple the computational engine 134 and/or the second data bus 203 to the first data bus 202 based on the path selection signal PSS. The computational memory 150 may transmit data stored in the computational memory 150 as the memory data DQ1, DQ2, . . . , DQn to the routing circuit 210 through the first data bus 202 during the memory read operation and may receive the memory data DQ1, DQ2, . . . , DQn through the routing circuit 210 and the first data bus 202 during the memory write operation. Here, n may be an integer equal to or greater than 4. When the routing circuit 210 connects the memory controller 133 to the computational memory 150, the routing circuit 210 may transmit data transmitted from the memory controller 133 to the computational memory 150 as the memory data DQ1, DQ2, . . . , DQn through the first data bus 202. In addition, the routing circuit 210 may transmit the memory data DQ1, DQ2, . . . , DQn transmitted from the computational memory 150 through the first data bus 202 to the memory controller 133. When the routing circuit 210 connects the computational engine 134 to the computational memory 150, the routing circuit 210 may provide the memory data DQ1, DQ2, . . . , DQn transmitted from the computational memory 150 through the first data bus 202 to the computational engine 134 as second computational data PD2 through the second data bus 203.

The computational memory 150 may include a memory cell array 221, a command address control circuit 222, and a data input/output circuit 223. The memory cell array 221 may include a plurality of memory cells capable of storing data. The memory cell array 221 may include a plurality of word lines arranged in a column direction and a plurality of bit lines arranged in a row direction, and the plurality of memory cells may be coupled at intersections at which the plurality of word lines and the plurality of bit lines intersect. The command address control circuit 222 may receive the memory command address signal CA through the command address bus 201. The command address control circuit 222 may decode and latch the memory command address signal CA to generate an internal command signal and an internal address signal of the computational memory 150. The internal command signal may be provided to the memory cell array 221 and the data input/output circuit 223, and the memory cell array 221 and the data input/output circuit 223 may perform the memory write operation and the memory read operation based on the internal command signal. The internal address signal may be provided to the memory cell array 221, and the memory cell array 221 may select a specific word line among the plurality of word lines and a specific bit line among the plurality of bit lines based on the internal address signal such that a memory cell coupled to the specific word line and the specific bit line may be accessed. The data input/output circuit 223 may generate the memory data DQ1, DQ2, . . . , DQn from data read from the memory cell array 221 during the memory read operation and may output the memory data DQ1, DQ2, . . . , DQn through the first data bus 202. The data input/output circuit 223 may receive the memory data DQ1, DQ2, . . . , DQn transmitted through the first data bus 202 during the memory write operation and may provide the received data to the memory cell array 221.

The computational engine 134 may include a global buffer 231, a plurality of processing elements 232, and a register 233. The global buffer 231 may be coupled to the internal bus 136 and may receive the first computational data PD1 transmitted through the internal bus 136. The global buffer 231 may store the first computational data PD1 and may provide the first computational data PD1 to the processing elements 232 such that the computational engine 134 may perform a computational operation. The processing elements 232 may receive the first computational data PD1 from the global buffer 231 and may receive the second computational data PD2 through the second data bus 203. The processing elements 232 may perform a computational operation on the first and second computational data PD1 and PD2 to generate the computation result data PRD. The processing elements 232 may output the computation result data PRD to the register 233. The register 233 may store the computation result data PRD and may output the computation result data PRD to the routing circuit 210 through the second data bus 203. The computation result data PRD may be transmitted to the computational memory 150 through the first data bus 202.

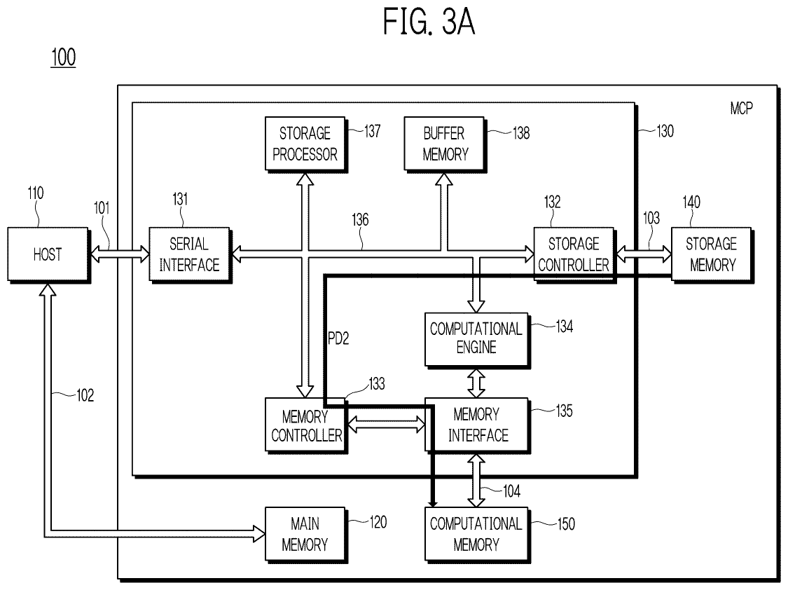

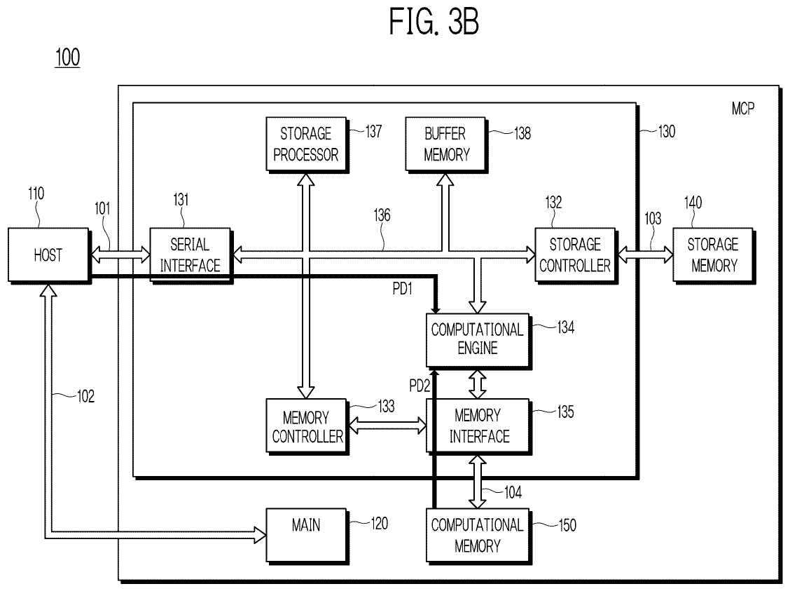

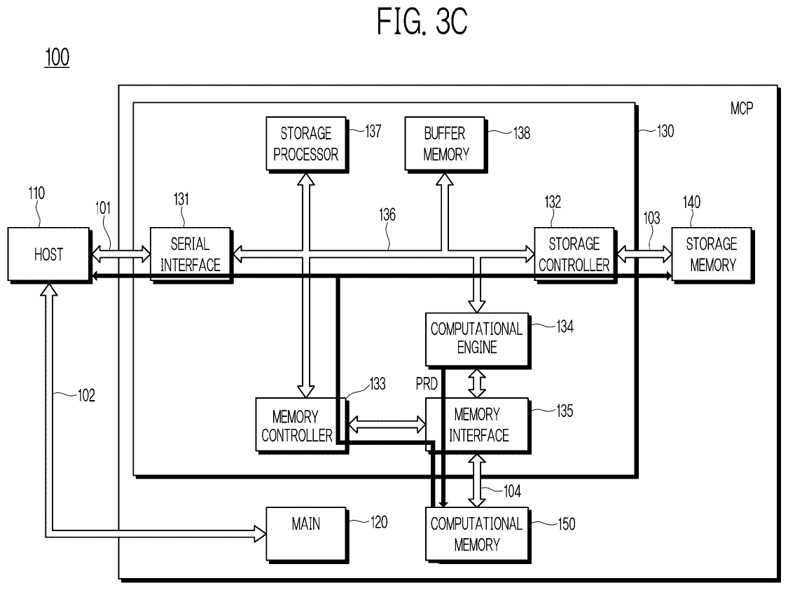

FIGS. 3A to 3C are diagrams illustrating operations of the computing system 100 according to an embodiment of the present disclosure. Referring to FIGS. 1 to 3C, a computational operation of the computing system 100 according to an embodiment of the present disclosure is described as follows. The host 110 may provide the first command address signal and the second computational data PD2 to the storage controller device 130 through the serial bus 101. The storage controller 132 may generate the storage write command address signal based on the first command address signal and may transmit the storage write command address signal and the second computational data PD2 to the storage memory 140 through the storage bus 103. The storage memory 140 may store the second computational data PD2 in the storage memory 140 based on the storage write command address signal.

Referring to FIG. 3A, in order to perform the computational operation, the second computational data PD2 stored in the storage memory 140 may be directly moved to the computational memory 150. The host 110 may transmit the first command address signal and the second command address signal to the storage controller device 130 through the serial bus 101. The storage controller 132 may generate the storage read command address signal based on the first command address signal and may transmit the storage read command address signal to the storage memory 140 through the storage bus 103. The storage memory 140 may read the second computational data PD2 stored in the storage memory 140 based on the storage read command address signal and may transmit the second computational data PD2 to the storage controller 132 through the storage bus 103. The memory controller 133 may generate a memory write command address signal based on the second command address signal and may provide the memory write command address signal to the memory interface 135. The memory interface 135 may determine that the memory write command address signal is generated based on the second command address signal and may couple the first data bus 202 to the memory controller 133. The memory interface 135 may transmit the memory write command address signal to the computational memory 150 through the command address bus 201. The storage controller 132 may output the second computational data PD2 to the internal bus 136, and the memory controller 133 may receive the second computational data PD2 through the internal bus 136. The memory controller 133 may provide the second computational data PD2 to the memory interface 135, and the memory interface 135 may transmit the second computational data PD2 to the computational memory 150 through the first data bus 202. The computational memory 150 may store the second computational data PD2 in the computational memory 150 based on the memory write command address signal. In an embodiment, the host 110 may transmit the selection command address signal to the storage controller device 130 before providing the first and second command address signals. The memory controller 133 may generate the path selection signal PSS illustrated in FIG. 2 based on the selection command address signal, and the memory interface 135 may couple the first data bus 202 to the memory controller 133 based on the path selection signal PSS. After the first data bus 202 is coupled to the memory controller 133 based on the path selection signal PSS, the second computational data PD2 may be moved from the storage memory 140 to the computational memory 150.

After the second computational data PD2 is moved from the storage memory 140 to the computational memory 150, the storage controller device 130 may perform the computational operation through the computational engine 134. Referring to FIG. 3B, the host 110 may transmit a computation command address signal to the storage controller device 130 through the serial bus 101. In addition, the host 110 may transmit the first computational data PD1 to the storage controller device 130 through the serial bus 101. The computational engine 134 may receive the first computational data PD1 through the internal bus 136 and may store the first computational data PD1. The memory controller 133 may generate the memory read command address signal based on the computation command address signal. The memory interface 135 may determine that the memory read command address signal is generated based on the computation command address signal and may couple the first data bus 202 to the computational engine 134. The memory interface 135 may transmit the memory read command signal to the computational memory 150. The computational memory 150 may read the second computational data PD2 stored in the computational memory 150 based on the memory read command signal and may transmit the second computational data PD2 through the first data bus 202. The memory interface 135 may provide the second computational data PD2 transmitted through the first data bus 202 to the computational engine 134 through the second data bus 203. The computational engine 134 may perform a computational operation on the first computational data PD1 and the second computational data PD2. The computational engine 134 may perform the computational operation on the first computational data PD1 and the second computational data PD2 to generate computation result data PRD. In an embodiment, the host 110 may transmit the selection command address signal to the storage controller device 130 before providing the computation command address signal. The memory controller 133 may generate the path selection signal PSS illustrated in FIG. 2 based on the selection command address signal, and the memory interface 135 may couple the first data bus 202 to the computational engine 134 based on the path selection signal PSS.

Referring to FIG. 3C, the computational engine 134 may output the computation result data PRD to the memory interface 135, and the memory interface 135 may transmit the computation result data PRD to the computational memory 150. The computational memory 150 may store the computation result data PRD in the computational memory 150. The computational memory 150 may store the computation result data PRD in the computational memory 150 based on the memory write command address signal. For example, the memory write command address signal may be generated based on the computation command address signal. The memory controller 133 may generate the memory write command address signal after the memory read command address signal is generated based on the computation command address signal and after a sufficient time elapses for the computational engine 134 to perform the computational operation. In an embodiment, when or before the computational operation of the computational engine 134 is completed, the host 110 may provide the second command address signal to the storage controller device 130 such that the computation result data is stored in the computational memory 150, and the memory controller 133 may generate the memory write command address signal based on the second command address signal.

The host 110 may read the computation result data PRD stored in the computational memory 150 or may move the computation result data PRD from the computational memory 150 to the storage memory 140. When the host 110 reads the computation result data, the host 110 may transmit the second command address signal to the storage controller device 130 through the serial bus 101, and the memory controller 133 may generate the memory read command address signal based on the second command address signal and may transmit the memory read command address signal to the computational memory 150. The computational memory 150 may read the computation result data PRD based on the memory read command address signal and may transmit the computation result data PRD through the second memory bus 104. The computation result data PRD may be transmitted to the internal bus 136 through the memory interface 135 and the memory controller 133. The serial interface 131 may transmit the computation result data PRD to the host 110 through the serial bus 101.

When the computation result data PRD is moved from the computational memory 150 to the storage memory 140, the host 110 may transmit the first command address signal and the second command address signal to the storage controller device 130 through the serial bus 101. The memory controller 133 may generate the memory read command address signal based on the second command address signal and may transmit the memory read command address signal to the computational memory 150. The computational memory 150 may read the computation result data PRD based on the memory read command address signal and may transmit the computation result data PRD through the second memory bus 104. The computation result data PRD may be transmitted to the internal bus 136 through the memory interface 135 and the memory controller 133. The storage controller 132 may generate the storage write command address signal based on the first command address signal. The storage controller 132 may transmit the storage write command address signal and the computation result data PRD transmitted through the internal bus 136 to the storage memory 140 through the storage bus 103. The storage memory 140 may store the computation result data PRD in the storage memory 140 based on the storage write command address signal.

In the related art, when the host performs a computational operation, the host had to move a large amount of computational data from the storage memory to the main memory. However, because a bandwidth of the serial bus is smaller than a bandwidth of the first memory bus, the serial bus may become a bottleneck in moving the computational data. The computing system 100 according to an embodiment of the present disclosure may perform a fast computational operation without involvement of the host 110 by including the computational engine 134 and the computational memory 150 in the storage controller device 130. Because, in an embodiment, a large amount of computational data may be moved from the storage memory 140 to the computational memory 150 within the storage controller device 130 without use of the serial bus 101, a time and/or latency required to move the computational data may be reduced. In an embodiment, the computational engine 134 may receive computational data having a relatively small capacity, such as vector data, from the host 110 and may receive computational data having a relatively large capacity, such as weight data, from the computational memory 150, and thus may perform an efficient and fast computational operation. Because, in an embodiment, the storage controller device 130 may perform a computational operation in parallel with and/or together with the host 110, enhanced AI computation and HPC (High Performance Computation) functions may be supported, and because a design of the host 110 does not need to be changed, high compatibility may be achieved.

In an embodiment, the host 110 may store both the first and second computational data PD1 and PD2 in the storage memory 140, and the storage controller device 130 may move the first computational data PD1 to the global buffer 231 of the computational engine 134 through the internal bus 136 and may move the second computational data PD2 from the storage memory 140 to the computational memory 150, and the plurality of processing elements 232 may perform a computational operation on the first computational data PD1 provided from the global buffer 231 and the second computational data PD2 provided from the computational memory 150.

In an embodiment, the host 110 may sequentially provide the first and second computational data PD1 and PD2 to the storage controller device 130. The first computational data PD1 may be stored in the global buffer 231 of the computational engine 134, and the second computational data PD2 may be stored in the computational memory 150. The plurality of processing elements 232 may perform a computational operation on the first computational data PD1 provided from the global buffer 231 and the second computational data PD2 provided from the computational memory 150.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A storage controller device comprising:
a serial interface coupling a host and an internal bus;
a storage controller coupled to the internal bus and coupled to a storage memory through a storage bus;
a memory controller coupled to the internal bus;
a computational engine coupled to the internal bus; and
a memory interface coupled to a computational memory through a memory bus and configured to selectively couple the computational engine and the memory controller to a data bus of the memory bus based on a command address signal.

2. The storage controller device of claim 1, wherein the computational engine is configured to perform a computation on first computational data provided through the internal bus and second computational data provided from the computational memory through the memory interface to generate computation result data.

3. The storage controller device of claim 2, wherein the first computational data is configured to be provided by the host.

4. The storage controller device of claim 2, wherein the computational engine is configured to output the computation result data to the memory interface.

5. The storage controller device of claim 1, wherein the memory interface is configured to couple the memory controller and the computational memory based on a memory command address signal, and configured to couple the computational engine and the computational memory based on a computation command address signal.

6. The storage controller device of claim 1, wherein the memory interface comprises a routing circuit configured to couple one of the memory controller and the computational engine to the data bus of the memory bus based on the command address signal.

7. The storage controller device of claim 6, wherein the computational engine comprises:
a global buffer configured to store first computational data provided through the internal bus;
a plurality of processing elements configured to receive the first computational data from the global buffer, configured to receive second computational data from the memory interface, and configured to perform a computation on the first and second computational data to generate computation result data; and
a register configured to store the computation result data.

8. The storage controller device of claim 7, wherein the computational memory is coupled to the routing circuit through a first data bus, and the register and the plurality of processing elements are coupled to the routing circuit through a second data bus.

9. A computing system comprising:
a host coupled to a main memory through a first memory bus; and
a storage controller device coupled to the host through a serial bus, coupled to a storage memory through a storage bus, and coupled to a computational memory through a second memory bus,
wherein the storage controller device is configured to perform a computation on first computational data transmitted from the host through the serial bus and second computational data provided from the computational memory through the second memory bus.

10. The computing system of claim 9, wherein the storage controller device is configured to generate computation result data by performing the computation on the first and second computational data, and configured to provide the computation result data to one of the host, the storage memory, and the computational memory.

11. The computing system of claim 9, wherein the storage controller device comprises:
a serial interface coupling the serial bus and an internal bus;
a storage controller coupling the internal bus and the storage bus;
a memory controller coupled to the internal bus;
a computational engine coupled to the internal bus; and
a memory interface coupled to the memory controller, the second memory bus, and the computational engine,
wherein the computational engine is configured to receive the first computational data through the internal bus, configured to receive the second computational data through the second memory bus and the memory interface, and configured to perform the computation on the first and second computational data.

12. The computing system of claim 11, wherein the memory interface is configured to selectively couple a data bus of the second memory bus to the memory controller and the computational engine based on a command address signal.

13. The computing system of claim 11, wherein the memory interface comprises a routing circuit configured to couple a data bus of the second memory bus to one of the memory controller and the computational engine based on a command address signal.

14. The computing system of claim 9, wherein the storage controller device, the storage memory, and the computational memory are packaged as a single package.

15. The computing system of claim 9, wherein the main memory, the storage controller device, the storage memory, and the computational memory are packaged as a single package.

16. A method of operating a computing system, comprising:
providing, by a host, first computational data to a storage memory through a storage controller device;
directly moving, by the storage controller device, the first computational data stored in the storage memory to a computational memory;
providing, by the host, second computational data to the storage controller device, and providing, by the computational memory, the first computational data to the storage controller device; and
performing, by the storage controller device, a computational operation on the first computational data and the second computational data.

17. The method of claim 16, wherein the providing of the first computational data by the host comprises:
Providing, by the host, the first computational data to the storage controller device through a serial bus;
Providing, by the storage controller device, the first computational data to the storage memory through a storage bus; and
Storing, by the storage memory, the first computational data.

18. The method of claim 16, wherein the directly moving of the first computational data comprises:
Providing, by the storage memory, the first computational data to the storage controller device;
Providing, by the storage controller device, the first computational data to the computational memory; and
Storing, by the computational memory, the first computational data.

19. The method of claim 16, further comprising generating computation result data by performing a computational operation on the first computational data and the second computational data, and
providing, by the storage controller device, the computation result data to the computational memory.
